(19) United States
(12) Patent Application Publication
(10) Pub. No.: US 2009/0310318 A1
(43) Pub. Date: Dec. 17, 2009

(54) ATTACHING A LEAD-FREE COMPONENT TO A PRINTED CIRCUIT BOARD UNDER LEAD-BASED ASSEMBLY CONDITIONS

(75) Inventor: Mudasir Ahmad, Santa Clara, CA (US)

Correspondence Address: BAINWOOD HUANG & ASSOCIATES LLC, 2 CONNECTOR ROAD, WESTBOROUGH, MA, 01581, US

(73) Assignee: Cisco Technology, Inc., San Jose, CA (US)

(21) Appl. No.: 12/139,783

(22) Filed: Jun. 16, 2008

(51) Int. Cl. H05K 7/00; B23K 31/02; B23P 19/00

(52) U.S. Cl. 361/760; 228/123.1; 29/739

(57) ABSTRACT

A technique for attaching components to PCBs involves providing a lead-free component and a PCB. The lead-free component has a package and lead-free component contacts, and the PCB has PCB contacts. The technique further involves disposing (e.g., printing) solder paste between the lead-free component contacts of the lead-free component and the PCB contacts of the PCB. The solder paste includes lead (Pb), a second metal (e.g., tin (Sn) and a third metal (e.g., Bismusth (Bi)). The technique further involves applying heat to melt the solder paste and form solder joints between the package of the lead-free component and the PCB contacts of the PCB. Such a technique is capable of concurrently mounting lead-free components as well as lead-based components to a PCB under lead-based assembly conditions (e.g., a temperature environment which does not exceed 230 degrees Celsius).

### BACKGROUND

One conventional circuit board assembly approach involves mounting lead-based parts (i.e., integrated circuit (IC) devices having lead-based external terminals) to a printed circuit board (PCB) using lead-based solder such as tin-lead (SnPB). An example of a lead-based part is a lead-based ball grid array (BGA) device having (i) a device package and (ii) a high density array of lead-based solder balls which extends from one side of the device package.

In the context of a conventional surface mount technology (SMT) assembly process, specialized equipment (e.g., stencil and squeegee equipment) prints solder paste containing the lead-based solder onto SMT pads of the PCB. Pick-and-place equipment then deposits the lead-based parts over the PCB and in contact with the printed solder paste. An oven then applies heat to activate flux within the solder paste, and to melt the lead-based solder (i.e., to liquefy and mix the lead-based solder in the solder paste and the external terminals of the devices) thus forming solder joints between the lead-based parts and the PCB.

Lead-free parts, which conventionally mount to PCBs using lead-free solder rather than lead-based solder, differ from lead-based parts in that there is no intentionally included or added lead in the lead-free parts. As a result, even though the lead-free parts may contain some impurities (e.g., incidental and/or inherent trace quantities of lead), the external terminals of the lead-free parts are substantially free of lead (e.g., less than 1000 PPM) and any trace amount of lead is insufficient to form a significant amount of lead alloy. Standards such as those of the Joint Electron Device Engineering Council (JEDEC) and the Restriction of Hazardous Substances (ROHS) set forth more formal requirements for lead-free compliancy.

### BRIEF DESCRIPTION OF THE DRAWINGS

The foregoing and other objects, features and advantages will be apparent from the following description of particular embodiments of the invention, as illustrated in the accompanying drawings in which like reference characters refer to the same parts throughout the different views. The drawings are not necessarily to scale, emphasis instead being placed upon illustrating the principles of various embodiments of the invention.

FIG. 1 is a block diagram of a circuit board assembly system which is arranged to simultaneously mount both lead-free components and lead-based components to a PCB under lead-based assembly conditions.

FIG. 2 is a perspective view of an assembled circuit board having both lead-free components and lead-based components which connect to a PCB via lead-based solder joints.

FIG. 3 is a cross-sectional diagram of various interacting parts during assembly of the circuit board in FIG. 2.

FIG. 4 shows a phase diagram illustrating certain experimentally determined behavior of lead-based solder which includes Bismuth (Bi).

FIG. 5 shows some experimental data supporting the ability of Bismuth (Bi) in reducing melting temperature in the presence of lead-free solder balls of various diameters.

FIG. 6 is a flowchart of a procedure for attaching both lead-free components and lead-based components to a PCB under lead-based assembly conditions

### DETAILED DESCRIPTION

### Overview

The melting temperature for traditional tin-lead solder is 183 degrees Celsius. During a conventional lead-based assembly process, the assembler typically applies a temperature which is 40 degrees higher than the tin-lead solder melting temperature (i.e., 223 degrees Celsius) since the oven typically has a conveyor configuration which exposes each assembly to heat for only a very short amount of time (e.g., 90 seconds). This higher temperature ensures that all of the tin-lead solder melts and mixes to form reliable solder joints.

The melting temperatures for lead-free solders (e.g., SnCu, SnAg, etc.) are higher than that of lead-based solder, and assemblers still apply temperatures which are 40 degrees higher than the lead-free solder melting temperatures to ensure thorough solder melting as the assemblies quickly pass through the conveyor oven. Accordingly, during a conventional lead-free assembly process, if the lead-free solder melting temperature is 217 degrees Celsius, the assembler applies a temperature which is 40 degrees higher (i.e., 257 degrees Celsius), thus comprehensively melting all of the lead-free solder to form reliable lead-free solder joints.

It should be understood that there are deficiencies to the above-described conventional circuit board assembly approaches. For example, the above-described conventional circuit board assembly approaches are inadequate for simultaneously mounting lead-based and lead-free components to the same PCB. This capability would nevertheless be worthwhile since part manufacturers are moving away from lead-based parts toward lead-free parts due to stricter government regulations and environmental concerns.

Unfortunately, attempts to come up with a reliable soldering solution have been generally unsuccessful. For example, if one tried to concurrently solder lead-based parts and lead-free parts to the same PCB using lead-free solder having a melting temperature of 217 degrees Celsius, the assembler will apply a temperature of 257 degrees Celsius during the short oven exposure time of the assembly process. Such a high temperature most likely will void at least some lead-based part manufacturer warrantees as well as possibly damage some of the lead-based parts.

As another example, if one tried to concurrently solder lead-based parts and lead-free parts to the same PCB using traditional tin-lead solder having a melting temperature of 183 degrees Celsius, the assembler would apply a temperature of 223 degrees Celsius during the short oven exposure time of the assembly process. Unfortunately, this lower temperature is inadequate to ensure proper melting and mixing of the lead-free solder structures (e.g., the lead-free solder balls of lead-free BGAs). Accordingly, an attempt to solder the lead-free parts using traditional tin-lead solder at this lower temperature would result in only partial melting and mixing, if any, and the poorly formed solder joints would be highly susceptible to failure during shipping, handling, in the field, etc.

In contrast to the above-described conventional circuit board assembly approaches, embodiments of the invention are directed to techniques for attaching lead-free components to a PCB under lead-based assembly conditions. Along these lines, it has been determined that introduction of small amounts of Bismuth (Bi) into a tin-lead (SnPb) solder is capable of reducing the melting point of lead-free component contacts (e.g., lead-free solder balls of lead-free BGA devices) by 5 degrees Celsius or more. Moreover, experiments have shown that the use of solder containing lead (Pb), tin (Sn) and Bismuth (Bi) under lead-based circuit board assembly conditions (e.g., a temperature environment which remains substantially between 212 degrees Celsius and 222 degrees Celsius) results in adequate melting, mixing and solder joint formation. Such techniques are thus well-suited for simultaneously mounting both lead-free components and lead-based components to a PCB under lead-based assembly conditions to avoid higher temperatures that would otherwise damage the lead-based components and void manufacturer warrantees.

One embodiment is directed to a technique which involves providing a lead-free component and a PCB. The lead-free component has a package and lead-free component contacts, and the PCB has PCB contacts. The technique further involves disposing (i.e., positioning) solder paste between the lead-free component contacts of the lead-free component and the PCB contacts of the PCB. The solder paste includes solder which has lead (Pb), a second metal (e.g., tin (Sn)) and a third metal (e.g., Bismusth (Bi)). The technique further involves applying heat to melt the solder. In particular, the solder within the solder paste melts and mixes with solder in the lead-free component contacts to form robust and reliable solder joints between the package of the lead-free component and the PCB contacts of the PCB. Such a technique is capable of concurrently mounting lead-free components as well as lead-based components to a PCB under lead-based assembly conditions (e.g., a temperature environment which does not exceed 230 degrees Celsius).

Another embodiment is directed to an assembled circuit board which includes a PCB having PCB contacts; a lead-free component initially having a package and lead-free component contacts; and solder joints which mount the package of the lead-free component to the PCB. The solder joints are formed from (i) solder paste having a solder containing lead (Pb), tin (Sn) and Bismuth (Bi) and (ii) the lead-free component contacts during a circuit board assembly process.

### Description of Example Embodiments

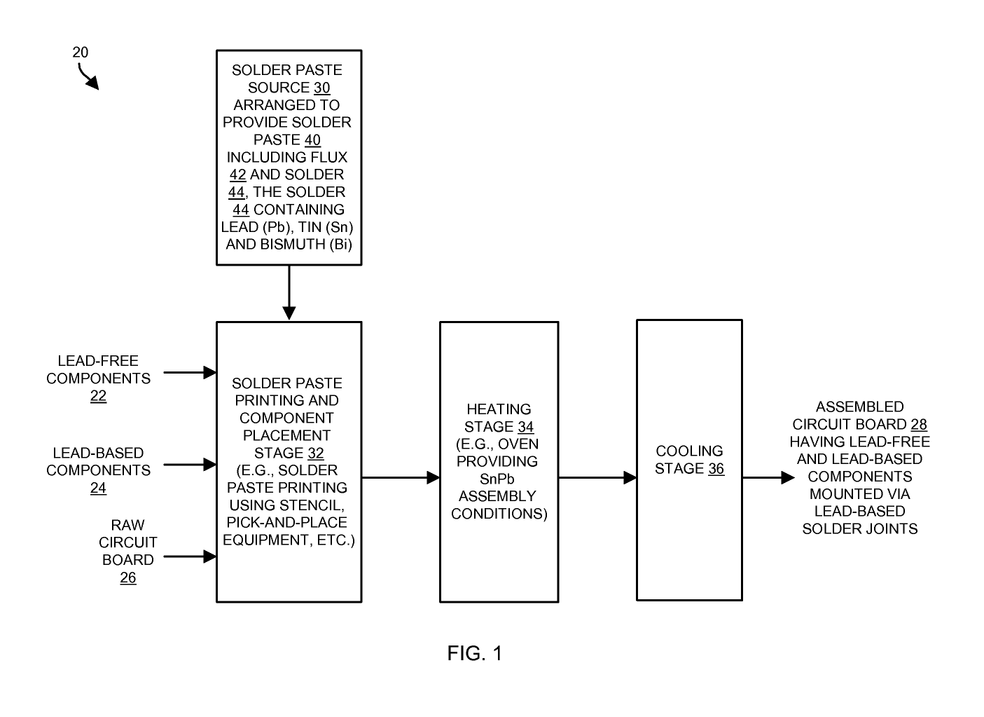

FIG. 1 shows a block diagram of a circuit board assembly system 20 which is arranged to simultaneously mount both lead-free components 22 and lead-based components 24 to a raw printed circuit board (PCB) 26 thus forming an assembled circuit board 28 under lead-based assembly conditions (i.e., the melting temperature for lead-based solder). The circuit board assembly system 20 includes a solder paste source 30, a printing and placement stage 32, a heating stage 34, and a cooling stage 36.

The solder paste source 30 is arranged to provide solder paste 40 which includes flux 42 and a lead-based solder 44. The lead-based solder 44 includes lead (Pb), tin (Sn) and Bismuth (Bi). As will be explained in further detail shortly, the percentage of Bismuth (Bi) in the solder paste 40 is less than 20 percent. Additionally, the melting temperature of the lead-based solder 44 within the soldering paste 40 is close to that of traditional lead-based solder or less (e.g., 183 degrees Celsius or less).

The printing and placement stage 32 is arranged to provide the solder paste 40 from the solder paste source 30 onto the raw PCB 26. In the context of an SMT assembly process, robotically controlled stencil and squeegee equipment print the solder paste 40 over mounting locations (e.g., SMT pads) of the PCB 26, and pick-and-place equipment places the lead-free components 22 and the lead-based components 24 over the mounting locations and in contact with the printed solder paste 40. Other forms of solder paste distribution are suitable for use as well such as deposition through a mask.

The heating stage 34 is arranged to apply heat appropriate for lead-based circuit board assembly, i.e., a temperature which does not exceed 230 degrees Celsius (e.g., 223 degrees Celsius or less). In some arrangements, the heating stage 34 includes an oven which provides a heated environment having a temperature which remains substantially between 212 degrees Celsius and 222 degrees Celsius. Such a temperature range is well-suited for melting the lead-based solder 44 without causing damage to the lead-based components 24 and without voiding manufacturer warrantees.

The cooling stage 36 is arranged to provide controlled cooling (e.g., gradual and uniform cooling) to form the assembled circuit board 28. The assembled circuit board 28 has both lead-free components 22 and lead-based components 24 which were robustly and reliably mounted to the PCB 26 using the lead-based solder 44.

It should be understood that the above-described circuit board assembly system 20 is capable of having additional stages which support the assembly process. These additional stages may include washing/cleaning stations, cutting stations, coating stations, testing stations, etc.

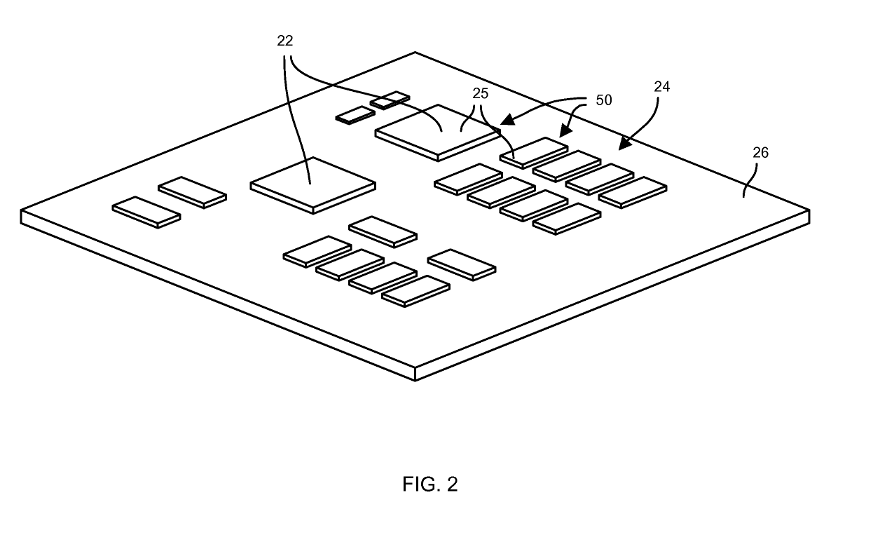

It should be further understood that various modifications could be made to the above-described circuit board assembly system 20. For example, the cooling stage 36 may be omitted from the system 20, and the assembled circuit boards 28 may be allowed to cool in an ambient room temperature environment. Further details will now be provided with reference to FIG. 2.

FIG. 2 shows an assembled circuit board 28 having both lead-free components 22 and lead-based components 24. Each component 22, 24 initially includes a device package 25 and a set of component contacts. During assembly, the component contacts and the lead-based solder 44 within the solder paste 40 melt and mix to form lead-based solder joints which attach the packages 25 to the PCB 26. As mentioned earlier, such solder joints 50 contain lead (Pb), tin (Sn), and Bismuth (Bi) in some arrangements.

In some situations, the lead-free components 22 may be parts in which a lead-based version is no longer available (e.g., the particular component manufacturer may have discontinued making the lead-based version). Such lead-free components 22 may include processors, memories, field programmable gate arrays (FPGAs), among others.

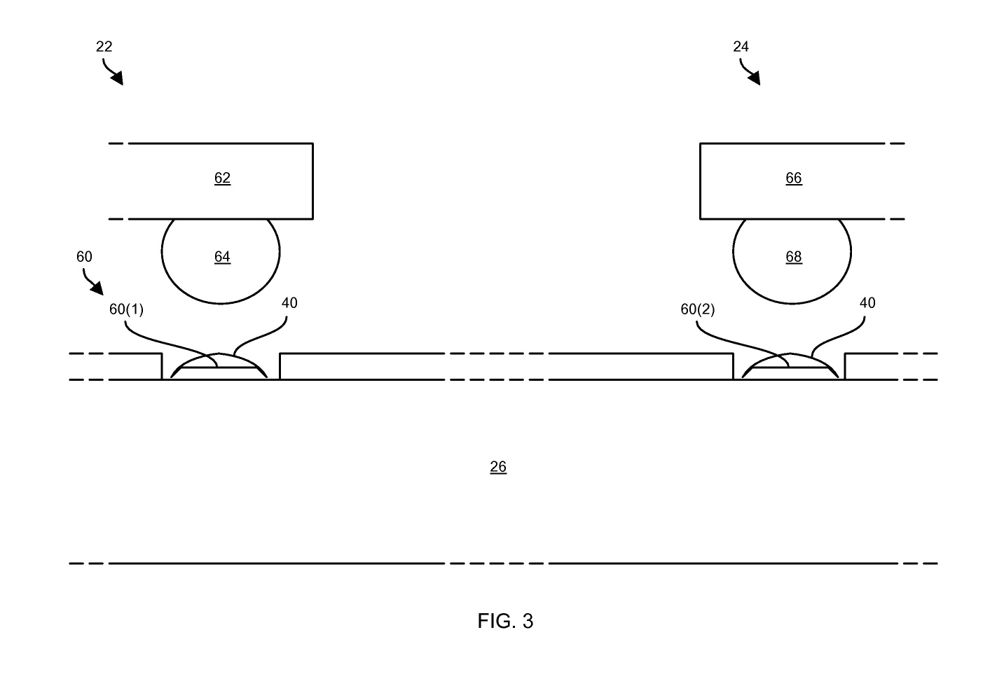

In contrast, the circuit board manufacturer may not be ready to switch to a completely lead-free assembly process. For instance, the manufacturer may have a number of lead-based components 24 remaining in stock or under agreement for use before switching from the lead-based components 24 to lead-free parts. Examples of such components 24 include Application Specific Integrated Circuits (ASICs), controllers, microprocessors, memories, and so on. Further details will now be provided with reference to FIG. 3.

FIG. 3 shows a cross-sectional view of various interacting parts during assembly of the circuit board 28 (also see FIGS. 1 and 2). As shown, the PCB 26 includes a set of PCB contacts 60(1), 60(2), . . . (collectively, PCB contacts 60). The lead-free component 22 includes a package substrate 62, and a set of lead-free component contacts 64 which extend from the package substrate 62. Only one lead-free component contact 64 is shown in FIG. 3 for simplicity but it should nevertheless be understood that each lead-free component 22 may include multiple lead-free component contacts 64 (e.g., a high density arrangement of lead-free component contacts 64).

Similarly, the lead-based component 24 includes a package substrate 66, and a set of lead-based component contacts 68 which extend from the package substrate 66. Again, only one lead-based component contact 68 is shown in FIG. 3 for simplicity but it should nevertheless be understood that each lead-based component 24 may include multiple lead-based component contacts 68 (e.g., a high density arrangement of lead-based component contacts 68).

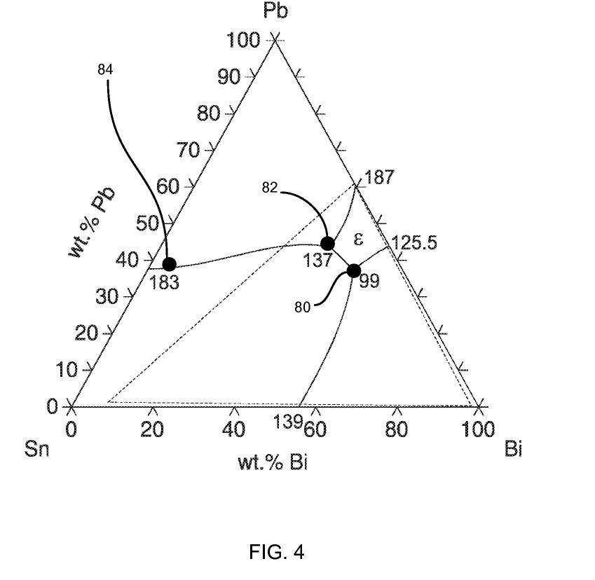

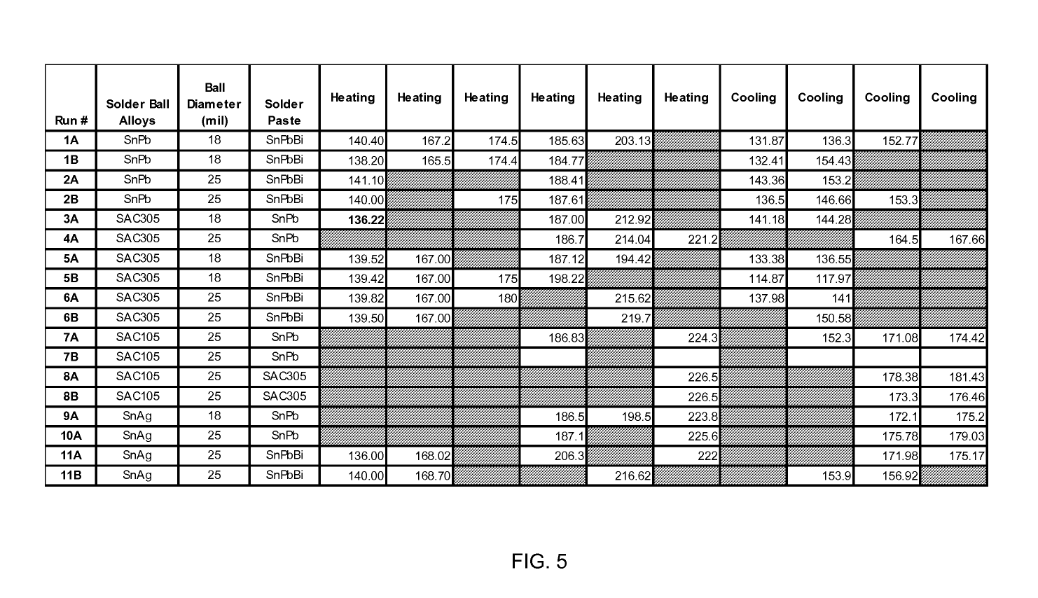

It should be understood that the PCB contacts 60 and the component contacts 64 68 are shown as SMT structures, i.e., SMT pads and solder balls, by way of example. In other arrangements, other soldering structures are suitable for use as well such as elongated PCB fingers, plated-through holes (PTHs), column-shaped contacts, gull-winged leads, pins, etc. In all of these structural arrangements, use of the lead-based solder paste 40 having lead-based solder 44 (FIG. 1) containing Bismuth (Bi) provides the ability to employ a relatively low solder melting temperature which is suitable for simultaneously mounting lead-free and lead-based parts to the PCB 26 in a reliable manner without damaging any of the components 22, 24. Further details will now be provided with reference FIGS. 4 and 5.

To better understand the effects of using lead-based solder 44 containing Bismuth (Bi) with lead-free components 22, a variety of different solder balls and paste volumes were considered. FIG. 4 shows a phase diagram which illustrates certain experimentally determined behavior of a lead-based solder which includes Bismuth (Bi). FIG. 5 shows some experimental data obtained using Differential Scanning Calorimetry (DSC) in the context of different solder ball and solder paste volumes.

The phase diagram of FIG. 4 shows the formation of ternary and peritectic alloys of Bismuth (Bi) with lead (Pb) and tin (Sn). In particular, the dot 80 shows where excess Bismuth (Bi) is capable of forming a segregated SnPbBi ternary eutectic which melts at a temperature of roughly 96 to 99 degrees Celsius. Since the operating temperatures of circuit boards are capable of reaching this temperature range, formation of the SnPbBi ternary eutectic should be avoided in order to prevent significant deterioration of solder joint reliability.

As shown by the dot 82 in the phase diagram of FIG. 4, a peritectic having a melting temperature of 137 degrees Celsius is capable of being formed as well. Formation of this peritectic is acceptable if the operating temperature of the assembled circuit board 28 (FIG. 1) does not reach this level.

As shown by the dot 84, an example combination of lead (Pb), tin (Sn), Bismuth (Bi) has a melting temperature of 183 degrees Celsius and which is suitable for use under lead-based assembly conditions. In particular, if the percentage of Bismuth (Bi) is less than 20%, the formation of the undesirable ternary eutectic (as well as the acceptable peritectic) is highly unlikely.

During accumulation of the data in FIG. 5, actual solder ball/solder paste samples were heated within a DSC machine and the enthalpy changes were recorded during the heating and cooling process. Spikes in the temperature/enthalpy curves were reviewed in order to determine the formation of different alloys in the solder ball/solder paste samples. The 96-99 degree Celsius SnPbBi ternary eutectic did not form in any of the samples.

Based on the collected data, significant reductions in melting temperature occurred when Bismuth (Bi) was used with lead-based solder. In particular, the introduction of small amounts of Bismuth (Bi) within lead-based solder used in mounting lead-free components effectively reduces the melting temperature of the lead-free component contacts of the lead-free components by varying degrees.

As further indicated by FIG. 5, for SAC305 solder balls, there is an approximately 1.5 to 5.58 degree Celsius reduction in peak temp for a 25 mil ball (the average reduction is 3.54 degrees Celsius). Additionally, for SAC305 solder balls, there is an approximately 14.7 to 18.5 degree Celsius reduction in peak temp for an 18 mil ball (the average reduction is 16.6 degrees Celsius). Furthermore, for SnAg solder balls, there is a 3.6 to 8.98 degrees Celsius reduction in peak temp for a 25 mil ball (the average reduction is 6.3 degrees Celsius).

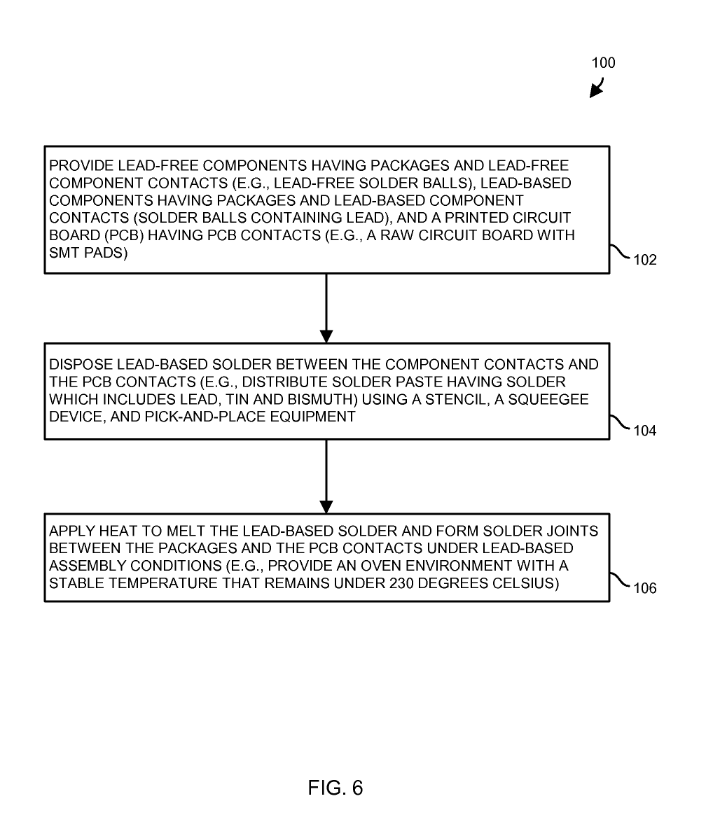

Moreover, following the DSC analysis, samples were cross-sectioned and the microstructures formed in the combined solder ball/solder paste combination were studied. This microstructure analysis confirmed that no segregation occurred between the tin-lead (SnPb) and Bismuth (Bi). Further details will now be provided with reference to FIG. 6.

FIG. 6 is a flowchart of a procedure 100 which is performed by a manufacturer when attaching both lead-free components 22 and lead-based components 24 to a PCB 26 under lead-based assembly conditions. In step 102, the manufacturer provides lead-free components 22, lead-based components 24 and the PCB 26. The lead-free components 22 have packages with lead-free component contacts (e.g., lead-free solder balls). Additionally, the lead-based components 24 have packages with lead-based component contacts (e.g., tin-lead solder balls).

In step 104, the manufacturer disposes lead-based solder paste 40 between the lead-free component contacts 64 of the lead-free components 22 and the PCB contacts 60 of the PCB 26. The manufacturer further disposes solder paste 40 between the lead-based component contacts 68 of the lead-free components 24 and the PCB contacts 60 of the PCB 26 (also see FIG. 3). In the context of an SMT process, robotically controlled stencil and squeegee equipment print the lead-based solder paste 40 over SMT pads of the PCB 26, and pick-and-place equipment then places the lead-free components 22 and the lead-based components 24 over the mounting locations and in contact with the printed solder paste 40.

In step 106, the manufacturer applies heat to melt the lead-based solder 44 within the solder paste 40 as well as solder of the components 22, 244 (e.g., the solder balls) to form solder joints 50 (FIG. 2) between the packages and the PCB contacts 60. The presence of Bismuth (Bi) within the lead-based solder 44 effectively reduces the melting temperature of the solder as well as the lead-free contacts 64 thus enabling the manufacturer to provide a soldering temperature that does not exceed 230 degrees Celsius (e.g., a temperature which remains substantially between 212 degrees Celsius and 222 degrees Celsius). Accordingly, the manufacturer does not need to provide a higher temperature such as 257 degrees Celsius used in conventional lead-free assembly processes and thus does not need to risk damaging the lead-based components 22 and does not need to void the warrantees of such components 22.

As described above, embodiments of the invention are directed to techniques for attaching lead-free components 22 to a PCB 26 under lead-based assembly conditions. To this end, it has been determined that introduction of small amounts of Bismuth (Bi) into a tin-lead (SnPb) solder is capable of reducing the melting point of lead-free component contacts (e.g., lead-free solder balls of lead-free BGA devices) by 5 degrees Celsius or more. Furthermore, experiments have shown that the use of solder containing lead (Pb), tin (Sn) and Bismuth (Bi) under lead-based circuit board assembly conditions (e.g., a temperature environment which remains substantially between 212 degrees Celsius and 222 degrees Celsius) results in adequate melting, mixing and solder joint formation. Such techniques are thus well-suited for simultaneously mounting both lead-free components 22 and lead-based components 24 to a PCB 26 under lead-based assembly conditions to avoid higher temperatures that would otherwise damage the lead-based components 24 and perhaps void manufacturer warrantees.

While various embodiments of the invention have been particularly shown and described, it will be understood by those skilled in the art that various changes in form and details may be made therein without departing from the spirit and scope of the invention as defined by the appended claims.

What is claimed is:

1. A method for mounting a component to a printed circuit board (PCB), the method comprising:
providing a lead-free component and the PCB, the lead-free component having a package and lead-free component contacts, the PCB having PCB contacts;
disposing solder paste between the lead-free component contacts of the lead-free component and the PCB contacts of the PCB, the solder paste including solder which has lead (Pb), a second metal and a third metal; and
applying heat to melt the solder and form solder joints between the package of the lead-free component and the PCB contacts of the PCB.

2. A method as in claim 1 wherein the second metal of the solder is tin (Sn); and
wherein the formed solder joints contain tin (Sn).

3. A method as in claim 2 wherein the third metal of the solder is Bismuth (Bi); and
wherein the formed solder joints contain Bismuth (Bi).

4. A method as in claim 3, further comprising:
disposing an additional amount of the solder paste between lead-based component contacts of a lead-based component and PCB contacts of the PCB, the lead-based component contacts of the lead-based component containing a substantial amount of lead (Pb).

5. A method as in claim 4 wherein each of the lead-free component contacts of the lead-free component and the lead-based component contacts of the lead-based component are surface mount technology (SMT) contacts;
wherein the PCB contacts of the PCB are SMT pads;
wherein (i) disposing the solder paste between the lead-free component contacts of the lead-free component and the PCB contacts of the PCB and (ii) disposing the additional amount of the solder paste between the lead-based component contacts of the lead-based component and PCB contacts of the PCB includes printing the solder paste onto the SMT pads through a stencil and placing the components over the printed solder paste using pick-and-place equipment; and
wherein the stencil and pick-and-place equipment form at least part of an SMT circuit board assembly system.

6. A method as in claim 5 wherein the lead-free component and the lead-based component are both Ball Grid Array (BGA) devices; and wherein the SMT contacts are solder balls.

7. A method as in claim 4 wherein the percentage of Bismuth (Bi) in the solder paste is less than 20 percent.

8. A method as in claim 7 wherein applying heat includes:
heating the solder paste to a soldering temperature which forms the solder joints and which does not exceed 230 degrees Celsius.

9. A method as in claim 8 wherein heating the solder paste includes:
passing the lead-free component, the lead-based component, the PCB and the solder paste through an oven which is arranged to provide a soldering environment having a temperature which remains substantially between 212 degrees Celsius and 222 degrees Celsius.

10. A circuit board assembly system, comprising:
a solder paste source arranged to provide solder paste including solder which has lead (Pb), a second metal and a third metal;
a printing and placement stage coupled to the solder paste source, the printing and placement stage being arranged to provide the solder paste from the solder paste source between lead-free component contacts of a lead-free component and printed circuit board (PCB) contacts of a PCB; and
a heating stage coupled to the printing and placement stage, the heating stage being arranged to melt the solder within the solder paste and form solder joints between a package of the lead-free component and the PCB contacts of the PCB.

11. A circuit board assembly system as in claim 10 wherein the second metal of the solder is tin (Sn); and wherein the formed solder joints contain tin (Sn).

12. A circuit board assembly system as in claim 11 wherein the third metal of the solder is Bismuth (Bi); and wherein the formed solder joints contain Bismuth (Bi).

13. A circuit board assembly system as in claim 12 wherein the printing and placement stage is further arranged to provide an additional amount of the solder paste between lead-based contacts of a lead-based component and the PCB contacts of the PCB, the lead-based contacts of the lead-based component containing lead (Pb).

14. A circuit board assembly system as in claim 13 wherein each of the lead-free component contacts of the lead-free component and the lead-based component contacts of the lead-based component are surface mount technology (SMT) contacts;
wherein the PCB contacts of the PCB are SMT pads; and
wherein the printing and placement stage includes a stencil and pick-and-place equipment which are arranged to print the solder paste onto the SMT pads and place the components over the printed solder paste.

15. A circuit board assembly system as in claim 14 wherein the lead-free component and the lead-based component are both Ball Grid Array (BGA) devices; and
wherein the SMT contacts are solder balls.

16. A circuit board assembly system as in claim 13 wherein the percentage of Bismuth (Bi) in the solder paste is less than 20 percent.

17. A circuit board assembly system as in claim 16 wherein the heating stage, when applying heat to melt the solder paste and form solder joints between the lead-free component contacts of the lead-free component and the PCB contacts of the PCB, is arranged to:
heat the solder paste to a soldering temperature which forms the solder joints and which does not exceed 230 degrees Celsius.

18. A circuit board assembly system as in claim 17 wherein heating the heating stage includes an oven which is arranged to heat the lead-free component, the lead-based component, the PCB and the solder paste to a temperature which is substantially between 212 degrees Celsius and 222 degrees Celsius.

19. An assembled circuit board, comprising:
a printed circuit board (PCB) having PCB contacts;
a lead-free component initially having a package and lead-free component contacts; and
solder joints which mount the package of the lead-free component to the PCB, the solder joints being formed from (i) solder paste having a solder containing lead (Pb), tin (Sn) and Bismuth (Bi) and (ii) the lead-free component contacts during a circuit board assembly process.

20. An assembled circuit board as in claim 1, further comprising:
a lead-based component initially having a package and lead-based component contacts containing lead (Pb); and
other solder joints which mount the lead-based component to the PCB, the other solder joints being formed from (i) an additional amount of the solder paste containing lead (Pb), tin (Sn) and Bismuth (Bi) and (ii) the lead-based component contacts during the circuit board assembly process.
